(19) United States
(12) Patent Application Publication
(10) Pub. No.: US 2005/0201068 A1
(43) Pub. Date: Sep. 15, 2005

(54) Replaceable LED module

(76) Inventors: Eric W. Kramer, Laguna Beach, CA (US); Thomas T. Nagano, Cerritos, CA (US); Kiem Lee, Whittier, CA (US)

Correspondence Address: Gordon E. Gray III;Suite 233, 4401 N. Atlantic Ave., Long Beach, CA, 90807, US

(21) Appl. No.: 10/798,752

(22) Filed: Mar. 10, 2004

(51) Int. Cl. H05K 1/03; H05K 7/14

(52) U.S. Cl. 361/752; 361/759; 174/256

(57) ABSTRACT

The present invention is an improved replaceable LED module. In particular, the present invention is directed to an environmentally resistant LED module for mounting on at least a pair of electrical leads with a non-conductive sheath surrounding conductive wire. A replaceable LED module preferably comprises a circuit board removably secured to a base by a set of snap tabs on the base. The base has two open ends and contains two electrical leads that traverse the base through the open ends. A protective gasket preferably covers the circuit board. The circuit board is preferably coated in acrylic conformal coating. The preferred circuit board has an LED and two contact teeth. Each contact tooth pierces the protective gasket and the non-conductive sheath of an opposing stranded electrical lead and makes electrical contact with the conductive wire. Thus, power is supplied to the LED from the leads while maintaining the protective gasket and sheath.

### TECHNICAL FIELD

The present invention is an improved replaceable LED module. In particular, the present invention is directed to an environmentally resistant LED module for mounting on at least one pair of electrical leads with a non-conductive sheath surrounding conductive wire.

### BACKGROUND ART

Generally, theater and auditorium lighting systems incorporate low voltage lighting strips within extrusions that are then placed on stairs, chairs, chair arms, armrests and walkways in order to illuminate walking areas for patrons and ushers. The prior art has contemplated different ways of arranging the light strips. Typically, the lighting strips are made up of wires soldered to light-emitting diodes (“LEDs”) or LED circuit boards. A number of lighting systems are known including U.S. Pat. Nos. 6,554,446, 6,283,612, 6,145,996, 6,116,748, 6,582,100, 6,386,733, and 5,954,425.

However, the theater and auditorium environments can often be damaging to electrical and lighting systems. For example, patrons can spill liquids on the floors and/or seats of these venues. Moreover, prior art systems, if any, that are resistant to these, often harsh, environmental installed conditions do not generally provide for the efficient replacement of an LED that has malfunctioned or burned out. It is frequently cumbersome to replace an LED from a lighting strip and commonly the entire lighting strip must be replaced and not just the damaged LED. The present invention provides an easier method of installing one or more LEDs while still providing an environmentally resistant module.

### SUMMARY OF THE INVENTION

The present invention is an improved replaceable LED module. In particular, the present invention is directed to an environmentally resistant LED module for mounting on at least a pair of electrical leads with a non-conductive sheath surrounding conductive wire. A replaceable LED module preferably comprises a circuit board removably secured to a base by a set of snap tabs on the base. The base has two open ends and contains two electrical leads that traverse the base through the open ends. A protective gasket preferably covers the circuit board. The circuit board is preferably coated in acrylic conformal coating. The preferred circuit board has an LED and two contact teeth. Each contact tooth pierces the protective gasket and the non-conductive sheath of an opposing stranded electrical lead and makes electrical contact with the conductive wire. Thus, power is supplied to the LED from the leads while maintaining the protective gasket and sheath.

### BRIEF DESCRIPTION OF THE DRAWINGS

The objects and features of the present invention, which are believed to be novel, are set forth with particularity in the appended claims. The present invention, both as to its organization and manner of operation, together with further objects and advantages, may best be understood by reference to the following description, taken in connection with the accompanying drawings.

FIG. 1 is a perspective view of a preferred embodiment of the invention installed on two electrical leads;

FIG. 2 is a partially exploded view of a preferred embodiment of the invention;

FIG. 3 is an exploded view of a preferred embodiment of a circuit board and a protective gasket for the invention; and,

FIG. 4 is a preferred embodiment of a protective gasket installed on a circuit board for the invention.

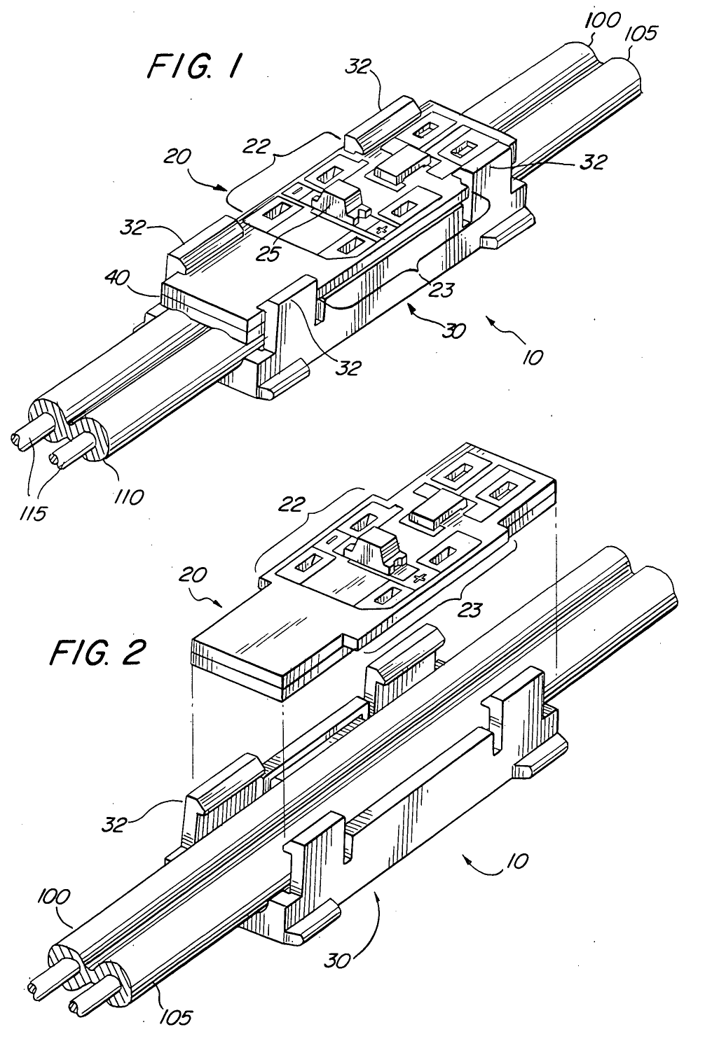

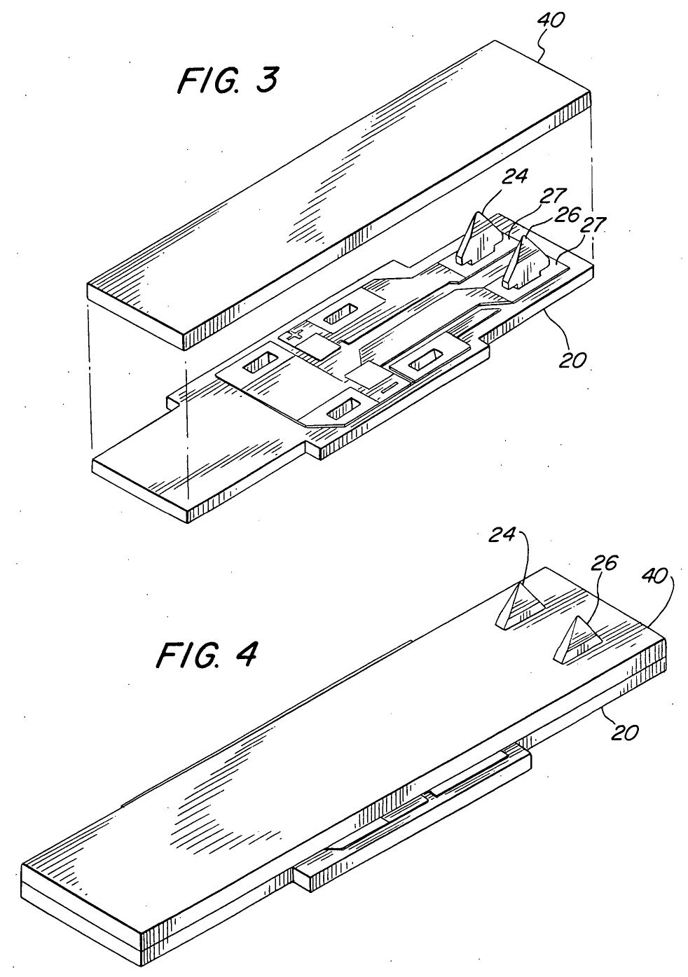

### DETAILED DESCRIPTION OF THE PREFERRED EMBODIMENTS

[1] The following description is provided to enable any person skilled in the art to make and use the invention and sets forth the best modes contemplated by the inventor of carrying out his invention. Various modifications, however, will remain readily apparent to those skilled in the art, since the general principles of the present invention have been defined herein specifically to provide an improved replaceable LED module.

[2] Referring now to FIG. 1, a preferred embodiment of the invention 10 is shown installed on two electrical leads 100 and 105. A preferred embodiment of the invention 10 is a complete modular unit comprising a light source and base for attaching the module to a set of leads. As shown, the preferred embodiment of the invention 10 comprises a circuit board 20 with a light emitting diode (“LED”) 25. The preferred embodiment of the circuit board 20 provides an LED connector for dome LEDs, surface mount LEDs, surface mount diodes, and “piranha-style” LEDs. The circuit board 20 is removably secured to a base 30 by a set of snap tabs 32. Preferably, the circuit board 20 comprises support lengths 22 and 23 of differing lengths that correspond to distances between snap tabs 32 on the base 30. By having support lengths 22 and 23 on the circuit board 20 and corresponding differing lengths between the snap tabs 32, a user can be guided to install the circuit board 20 on the base 30 with proper polarity.

[3] Preferably, the base 30 is open-ended and contains at least one pair of electrical leads 100 and 105 passing through the ends of the base 30. Additional leads can be present as well. For example, the use of 3 pairs of leads can provide Red-Green-Blue (RGB) LED functionality. The circuit board 20 is held snugly with the electrical leads 100 and 105 by the set of snap tabs 32. Preferably, a protective gasket 40 creates an environmentally protective seal between the circuit board 20 and the electrical leads 100 and 105.

[4] Referring now to FIG. 2, FIG. 2 shows the circuit board 20 and gasket 40 removed from the base 30 and leads 100, 105. Since the circuit board 20 and gasket 40 are preferably removable from the base 30, the LED 25 and/or the circuit board 20 becomes more easily replaceable when, inter alia, the LED burns out or is otherwise damaged. Furthermore, when the circuit board 20 is removed from the base 30, the base 30 can be positioned or re-positioned along the electrical leads 100 and 105 if desired.

[5] FIG. 3 shows a bottom side of a preferred embodiment of the circuit board 20 and gasket 40. The circuit board 20 preferably has a set of at least two contact teeth 24, 26 connected to the LED on the circuit board 20. The contact teeth 24, 26 are preferably supported on the circuit board 20 by shoulder mounts 27. The contact teeth 24, 26 are preferably an electrically conductive material such as copper with tin plating. Alternatively, the teeth can comprise, inter alia, gold, silver, platinum and/or other conductive materials. The teeth 24, 26 are preferably held vertical during production by a jig.

[6] The contact teeth 24, 26 are preferably sharp enough to pierce the gasket 40. The preferred gasket material is vinyl foam tape with acrylic adhesive. Thus, the gasket 40 forms a protective barrier on the circuit board 20 while the contact teeth 24, 26 provide a conductive pathway to the circuit board 20 and the LED 25. A preferred embodiment of the gasket 40 installed on the circuit board 20 is shown in FIG. 4. As shown in FIG. 4, the conductive teeth 24, 26 are visible after traversing the thickness of the gasket 40. The gasket 40 is preferably affixed to the circuit board 20 by pressure sensitive double-sided adhesive.

[7] Alternately, the gasket 40 can have pre-cut openings to allow the teeth 24, 26 to pass through the gasket 40 to allow electrical contact between the circuit board 20 and electrical leads. However, the gasket 40 should be sufficiently snug to the teeth 24, 26 to continue to provide protection for the circuit board 20.

[8] Returning to FIG. 1, the electrical leads 100 and 105 are usually stranded wires and typically have a non-conductive sheath 110 around electrically conductive wire 115. The contact teeth 24, 26 of the circuit board 20 preferably pierce the non-conductive sheath 110 to make electrical contact with the conductive wire 115. During insertion into the sheath 110, shoulder mounts 27 on the circuit board 20 support the teeth 24, 26. The preferred embodiments of the contact teeth 24, 26 are coated in wax that is removed when the teeth 24, 26 are inserted into the non-conductive sheath 110. Each contact tooth preferably makes electrical contact with an opposing electrical lead (e.g. 26 to 100 or 24 to 105). Additionally, the non-conductive sheath 110 will often grab and hold the teeth 24, 26 in place and in contact with the leads. Thus, power is supplied to the circuit board 20 from the electrical leads 100 and 105 via the contact teeth 24, 26 while the non-conductive sheath 110 and gasket 40 continue to provide protection from the installed environment to the electrical components of the invention. Preferably and additionally, the circuit board is coated in a protective sealant to provide additional protection from the installed environment. The preferred sealant is acrylic conformal coating.

[9] Thus, an improved replaceable LED module is described above that is capable of easy installation and replacement while offering improved environmental resistance. In each of the above embodiments, the different positions and structures of the present invention are described separately in each of the embodiments. However, it is the full intention of the inventor of the present invention that the separate aspects of each embodiment described herein may be combined with the other embodiments described herein. Those skilled in the art will appreciate that adaptations and modifications of the just-described preferred embodiment can be configured without departing from the scope and spirit of the invention.

[10] For example, the circuit board 20, except for the contact teeth 24, 26, can be coated in a protective sealant and held snugly to the non-conductive sheath of the electrical leads 100 and 105, thereby omitting the gasket 40. Other alternate embodiments could use additional contact teeth. Another alternate embodiment comprises a plastic circuit board with built-in circuit leads and LED(s) that then snaps onto the base. Therefore, it is to be understood that, within the scope of the appended claims, the invention may be practiced other than as specifically described herein.

1. An LED module comprising:
a circuit board secured to a base containing at least two electrical leads;
the circuit board having an LED and at least two contact teeth whereby each contact tooth makes electrical contact with one of the at least two electrical leads.

2. The LED module of claim 1 where the at least two electrical leads further comprise a non-conductive sheath and where each contact tooth pierces the non-conductive sheath to make electrical contact with one of the at least two electrical leads.

3. The LED module of claim 1 where a gasket with a thickness covers a side of the circuit board and where the at least two contact teeth traverse the thickness of the gasket to make electrical contact with the at least two electrical leads.

4. The LED module of claim 1 where the base further comprises a set of snap tabs whereby the circuit board is secured to the base by snapping the circuit board onto the base by the set of snap tabs.

5. The LED module of claim 1 where the circuit board is coated in a protective sealant.

6. An LED module comprising:
a circuit board secured to a base for containing at least two electrical leads having non-conductive sheathes;
the circuit board having an LED and at least two contact teeth whereby each contact tooth is sufficiently sharp to pierce the non-conductive sheath of an electrical lead and make electrical contact with the electrical lead.

7. The LED module of claim 6 where a gasket with a thickness covers a side of the circuit board and where the at least two contact teeth traverse the thickness of the gasket.

8. The LED module of claim 6 where the base further comprises a set of snap tabs whereby the circuit board is secured to the base by snapping the circuit board onto the base by the snap tabs.

9. The LED module of claim 6 where the base has two open ends and where at least two electrical leads can traverse the base through the open ends.

10. A replaceable LED module comprising:
a circuit board removably secured to a base by a set of snap tabs on the base; the base further having two open ends and containing two electrical leads that traverse the base through the open ends;
each electrical lead comprises a non-conductive sheath;
the circuit board having an LED and two contact teeth whereby each contact tooth pierces the non-conductive sheath of one electrical lead and makes electrical contact with the electrical lead.

11. The replaceable LED module of claim 10 further comprising a protective gasket with a thickness covering a side of the circuit board where the contact teeth traverse the thickness of the gasket.

12. The replaceable LED module of claim 10 where the circuit board further comprises a first support length and a second support length; where the first support length differs in length from the second support length; and where the set of snap tabs further comprise a first set of snap tabs separated by a first distance corresponding to the first support length and a second set of snap tabs separated by a second distance corresponding to the second support length.
